(19) United States
(12) Patent Application Publication
(10) Pub. No.: US 2014/0259656 A1
(43) Pub. Date: Sep. 18, 2014

(54) DATA LOGGER SENSOR COMPONENT ASSEMBLY AND TEST PROCESS

(71) Applicant: ONSET COMPUTER CORPORATION, Bourne, MA (US)

(72) Inventor: Jacob Lacourse, Middleboro, MA (US)

(73) Assignee: ONSET COMPUTER CORPORATION, Bourne, MA (US)

(21) Appl. No.: 13/837,153

(22) Filed: Mar. 15, 2013

(51) Int. Cl. H05K 3/34; G01D 15/00

(52) U.S. Cl. CPC H05K 3/34; G01D 15/00
USPC 29/840

(57) ABSTRACT

An process for assembling a data logger for logging a sensed condition of an environment includes the steps of (1) reflow soldering a partially complete data logger printed circuit board; (2) assembling a sensor component to the printed circuit board via a molded socket that utilizes elastomeric contacts to cause an electrical connection between leads of the sensor component and the conductors on the printed circuit board; and (3) performing a sensor component specific post assembly process that results in the sensor component meeting a plurality of operational specifications, wherein the sensor component specific process takes less than two hours to complete.

### FIELD

This disclosure relates to the field of data logger electronic component assembly and testing.

### BACKGROUND

Reflow assembly of certain sensor components causes deposition of harmful VOCs (inherent in various electronic processes) onto and into sensitive areas of such components. To ready sensor components assembled in this way for proper operation and compliance with published specifications requires an extensive and time-consuming reconditioning and recalibration process.

### SUMMARY

Methods and systems related to data logger assembly and testing processes described herein may include a method of assembling a sensor component whilst eliminating the need to recalibrate and or recondition the sensor after assembly.

Methods and systems of data logger assembly may include a method of assembling a data logger for logging a sensed condition of an environment. This method may include processing a data logger printed circuit board comprising a portion of components other than a sensor component through a reflow soldering process. Subsequent to the reflow process, assembling a sensor component that is preconfigured to meet a plurality of operational specifications into a molded socket that utilizes elastomeric contacts to cause an electrical connection between leads of the sensor component and the conductors on the printed circuit board, providing a completed printed circuit board assembly. After assembly this method may include performing a post-reflow process on the completed printed circuit board assembly that includes a sensor component specific process that results in the sensor component meeting the plurality of operational specifications and the sensor component specific process takes less than two hours to complete. In this process the sensor component may be a relative humidity sensor component. Also in this process the sensor component specific process may take less than two minutes to complete.

Methods and systems of data logger assembly may include a method of assembling a data logger for logging a sensed condition of an environment that includes taking a partially assembled data logger printed circuit board comprising a portion of components other than a sensor component and assembling a sensor component that is preconfigured to meet a plurality of operational specifications to the printed circuit board with a user serviceable assembly process, providing a completed printed circuit board assembly, and performing a process on the completed printed circuit board assembly that includes a sensor component specific process that results in the sensor component meeting the plurality of operational specifications and the sensor component specific process takes less than two hours to complete. In this process the sensor component may be a relative humidity sensor component. Further, in this process the sensor component specific process may take less than two minutes to complete

### BRIEF DESCRIPTION OF THE FIGURES

The invention and the following detailed description of certain embodiments thereof may be understood by reference to the following figures:

FIG. 1 depicts a prior art sensor device specific post reflow process;

FIG. 2 depicts perspective views of a printed circuit board with a socket mounted sensor component in various stages of assembly;

FIG. 3 depicts a sensor component being installed into a socket; and

FIG. 4 depicts an innovative sensor device specific post reflow process.

While described herein with reference to various embodiments, it is understood that, in all cases, unless otherwise specified, references to an “embodiment” or “embodiments” refer to one or more exemplary and non-limiting embodiments. Also, it is understood that, in all descriptions herein, unless otherwise specified, even when not explicitly being referenced to an “embodiment” or “embodiments” refer to one or more exemplary and non-limiting embodiments.

### DETAILED DESCRIPTION

FIG. 1 depicts a prior art sensor component assembly, reconditioning, calibration, and test process. This process includes reflow soldering the sensor component to a printed circuit board followed by a twenty-four baking process. The baking process is followed by a twenty hour rehydration process in a special chamber. After rehydration the parts are run in a “thunder” process for forty-eight hours. Finally the parts are tested and results of the thunder process are checked to ensure the parts meet the published specifications.

FIG. 2 depicts perspective views of a sensor component, printed circuit board layout, and socket material for connecting the component to the printed circuit board. The left figure shows the parts isolated. The right figure shows the selectively conductive socket material (e.g. zebra strip elastomeric connector) disposed between the sensor component and the lands on the printed circuit board. The selectively conductive socket material makes a suitable electrical connection between the component and the lands on the printed circuit board.

FIG. 3 depicts stages of assembly of a sensor component into a socket that is suitable for the user serviceable assembly process described herein. The left-most figure shows the selectively conductive elastomeric socket material from FIG. 2 installed in a socket body. The center figure shows installation of a sensor component into the socket body so that the electrical contacts on the component align with the conductive portions of the zebra strip elastomeric substrate, while isolating the contacts from each other. The right-most figure shows a top portion or lock ring positioned over the sensor component to lock the component in place by mechanically attachment to the socket body. This lock ring may provide the proper mounting force required per the elastomeric strip datasheets.

The socket body of FIG. 3 and the printed circuit board of FIG. 2 may be configured with mechanical attachment features that facilitate aligning the socket and holding the socket firmly in place to facilitate proper electrical and mechanical contact with the selectively conductive elastomeric material. Examples of such mechanical attachment features include drilled holes in the printed circuit board and snap-fit legs extending below a bottom of the socket body. Other mechanical attachment features, such as clips, threaded posts, heat staking, adhesive, and the like are contemplated and therefore included in the methods and systems described herein.

FIG. 4 depicts a sensor component assembly and test process based on the inventive methods and systems of data logger printed circuit board sensor component assembly described herein. This process involves assembling the socket body with selectively conductive elastomeric portion to the printed circuit board, followed by installing the sensor component into the socket as depicted in FIG. 3. An assembly testing process that includes a sensor component specific process (e.g. functional test) follows this assembly step. The process ends with validating that the sensor component complies with at least a portion of the published specifications for the sensor component. The sensor specific portion of this process may take less than two hours. In embodiments the sensor specific portion of this process may take less than thirty minutes, and even less than two minutes is possible. The sensor specific portion may be substantially shorter than the prior art, while achieving the same or better results regarding sensor component operation, at least because the prior art steps of drying, rehydration, and thundering are not required by using the assembly processes described herein.

In addition to a reduced cost and time saving assembly and test process, data loggers configured with this sensor component assembly process may facilitate user replacement in the field. Because sensors can be contaminated under normal use conditions it is desirable for the end user to have the ability to replace the sensor. When a sensor component is assembled with a reflow process, it is not feasible to have a customer perform a field replacement of the sensor component. Therefore, the user serviceable assembly process of the sensor component described and claimed herein will also permit the end user to easily attach a replacement sensor in the field.

Cost savings may be had as well with this process because a lower cost sensor component may be sourced due to the reduction in stresses being placed on it during assembly. Even with potentially increased costs of the plastic holder and elastomeric material, the net is a savings in costs.

What is claimed is:

1. A method of assembling a data logger for logging a sensed condition of an environment, comprising:
processing a data logger printed circuit board comprising a portion of components other than a sensor component through a reflow soldering process;
assembling a sensor component that is preconfigured to meet a plurality of operational specifications into a molded socket that utilizes elastomeric contacts to cause an electrical connection between leads of the sensor component and the conductors on the printed circuit board, providing a completed printed circuit board assembly; and
performing a post-reflow process on the completed printed circuit board assembly that includes a sensor component specific process that results in the sensor component meeting the plurality of operational specifications, wherein the sensor component specific process takes less than two hours to complete.

2. The method of claim 1, wherein the sensor component is a relative humidity sensor component.

3. The method of claim 1, wherein the sensor component specific process takes less than two minutes to complete.

4. A method of assembling a data logger for logging a sensed condition of an environment, comprising:
taking a partially assembled data logger printed circuit board comprising a portion of components other than a sensor component;
assembling a sensor component that is preconfigured to meet a plurality of operational specifications to the printed circuit board with a user serviceable assembly process, providing a completed printed circuit board assembly; and
performing a post-reflow process on the completed printed circuit board assembly that includes a sensor component specific process that results in the sensor component meeting the plurality of operational specifications, wherein the sensor component specific process takes less than two hours to complete.

5. The method of claim 4, wherein the sensor component is a relative humidity sensor component.

6. The method of claim 4, wherein the sensor component specific process takes less than two minutes to complete.
